(19) United States
(12) Patent Application Publication
(10) Pub. No.: US 2011/0088933 A1
(43) Pub. Date: Apr. 21, 2011

(54) LOW DIELECTRIC LOSS WIRING BOARD, MULTILAYER WIRING BOARD, COPPER FOIL AND LAMINATE

(76) Inventors: Satoru AMOU, Hitachi (JP); Hikaru Kagiwada, Matsuda (JP); Dai Hori, Hatano (JP)

(21) Appl. No.: 12/907,116

(22) Filed: Oct. 19, 2010

(30) Foreign Application Priority Data
Oct. 20, 2009 (JP) 2009-240975

(51) Int. Cl. H05K 1/09; B32B 5/02; B32B 15/08

(52) U.S. Cl. 174/257; 428/608; 428/612; 428/607

(57) ABSTRACT

A wiring board comprising a copper wiring, and an insulating layer which is a cured product of a resin composition containing a compound having a carbon-carbon unsaturated double bond as a cross-linking component,
the wiring board having a surface-treated layer formed on one or both sides of the copper wiring, and
the surface-treated layer having a metal layer (A) containing at least one metallic component selected from the group consisting of tin, zinc, nickel, chromium, cobalt and aluminium,
an oxide and/or hydroxide layer (B) of the metallic component on the metal layer (A),
an amino-silane coupling agent layer (C) having an amino group in its structure on the oxide and/or hydroxide layer (B), and
a vinyl-silane coupling agent layer (D) having a carbon-carbon unsaturated double bond on the amino-silane coupling agent layer (C).

### CLAIM OF PRIORITY

The present application claims priority from Japanese patent application serial No. 2009-240975, filed on Oct. 20, 2009, the content of which is hereby incorporated by reference into this application.

### FIELD OF THE INVENTION

The present invention relates to a wiring board, a multilayer wiring board, and a copper foil and a laminate for use in the same.

### BACKGROUND OF THE INVENTION

Recently, electronic devices are increasingly reduced in size and weight, and high-density fine wiring is required for wiring boards used for such devices by means of multilayering and finer wiring. In order to achieve higher reliability of high-density fine wiring, enhanced adhesion of an insulating layer and copper wiring is required, and smoothing of adhesion interface from the perspective of improving accuracy of etching processing is required.

Meanwhile, signal bands of information communication devices such as PHS and cellular phones, and CPU clock times of computers have reached GHz bands, becoming increasingly higher in frequencies. The transmission loss of electrical signals is expressed by the sum of dielectric loss, conductor loss and radiation loss. The higher the frequency of electrical signals, the greater the dielectric loss, conductor loss and radiation loss. Since the transmission loss attenuates the electrical signal and damages the reliability of the electrical signals, in wiring boards handling high frequency signals, measures for suppressing dielectric loss, conductor loss and radiation loss need to be taken.

The dielectric loss is proportional to the product of a square root of a relative permittivity of an insulator on which circuits are formed, a dielectric loss tangent, and a frequency of signals used. Therefore, selection of an insulating material having a low relative permittivity and dielectric tangent as an insulator can suppress an increase in dielectric loss.

To reduce the relative permittivity and dielectric tangent of the insulating material, a reduction in polarization of a resin structure constituting the same is effective. Meanwhile, heat resistance such as solder heat resistance is often required for wiring boards and multilayer wiring boards. Suggested insulating materials which have both the resin structure with low polarity and heat resistance include various low dielectric loss materials containing a thermosetting cross-linking component having a carbon-carbon double bond in its structure, and prepregs, laminates, wiring boards, multilayer wiring boards using the same are also suggested.

Examples include prepregs, laminates, wiring boards and multilayer wiring boards produced by impregnating a glass cloth with diene-based polymers such as polybutadiene described in JP-A No. 2008-266408, polyfunctional styrene compounds wholly having hydrocarbon skeletons, and a bismaleimide compound having a specific structure and curing the same with a peroxide.

There are many other examples including a resin composition comprising allylated polyphenylene ether (PPE) and triallyl isocyanate described in JP-A No. 9-246429 (1997), and the use of a polyphenylene ether resin having a terminal styrene group and triallyl isocyanate described in JP-A No. 2007-30326.

The conductor loss is generally reduced by lowering the surface roughness of copper wiring. However, reducing the surface roughness of copper wiring creates the new problem that the adhesiveness with an insulating material is lowered. High adhesion between copper wiring having a smooth surface and an insulating layer is also required from the perspective of reducing conductor loss.

If it is possible to reduce the surface roughness of the copper wiring in a multilayer wiring board using the aforementioned low dielectric loss material as an insulating layer, conductor loss and dielectric loss can be both reduced, and further the precision of fine wiring processing can be also improved. Such examples include the disclosures of JP-A Nos. 2007-30326 and 2005-89691, which are pre-adhesion treatment techniques by which a vinyl-silane coupling agent layer having a carbon-carbon unsaturated double bond in its structure is provided directly or via a metal layer of a different kind such as zinc on copper wiring.

In contrast, examples of techniques of improving the adhesive strength when an epoxy resin and a cyanate ester resin having relatively high dielectric loss is used as an insulating layer include, as in JP-T No. 2004-536220, providing a metal layer of a different kind selected from tin, silver, bismuth, nickel, lead, zinc, indium, palladium, platinum, gold, cadmium, ruthenium, cobalt, gallium and germanium on copper wiring, and then providing an amino-silane coupling agent layer on the metal layer.

Examples also include JP-A No. 2007-107080, in which a metal layer of a different kind such as tin, silver, bismuth, nickel, lead, zinc, indium and palladium is provided on copper wiring, a glass layer made of silicate ester, polysilazane, a bifunctional silane compound and other substances is provided on the metal layer, and a layer made of various silane coupling agents is provided on the glass layer.

These examples disclose the improvement in the chemical resistance of adhesion interface by providing a metal layer of a different kind such as tin, zinc, nickel, chromium, cobalt and aluminium on the copper wiring, and the enhancement of the adhesion of the interface by providing a silane coupling agent layer which can bind to a resin component constituting the insulating layer by a covalent bond.

However, achieving both the smoothing of the surface of the copper wiring and the adhesive strength between the copper wiring and the insulating layer comprising a low dielectric loss material has been insufficient.

An object of the present invention is to provide a multilayer wiring board using as an insulating layer a low dielectric loss material containing a cross-linking component having a carbon-carbon double bond in its structure and using copper wiring having a smooth surface as a wiring layer, the multilayer wiring board having high adhesive strength between the insulating layer and the copper wiring and a highly reliable adhesion interface, and to provide a copper foil, a laminate and a wiring board used for the same.

### SUMMARY OF THE INVENTION

We examined surface processing of a copper wiring having high adhesive strength for a low dielectric loss material containing a cross-linking component having a carbon-carbon double bond in its structure. As a result, we have found that by providing on the copper wiring an amino-silane coupling agent layer which is unlikely to directly react with compounds in the low dielectric loss material, the adhesive strength between the low dielectric loss material and the copper wiring is remarkably increased, and that the larger the thickness of the amino-silane coupling agent layer, the higher the adhesive strength. The effect of providing the amino-silane coupling agent layer on the copper wiring was higher than a conventional method of providing a layer of a vinyl-silane coupling agent (hereinafter referred to as vinyl-silane coupling agent) having a carbon-carbon double bond in its structure on the copper wiring.

However, Although the adhesive strength for the low dielectric loss material is improved by providing the amino-silane coupling agent layer on the copper wiring, there was found the new problem that partial peeling occurs at the interface between the copper wiring and the low dielectric loss material under high-humidity/temperature conditions. The peeling at the interface between the low dielectric loss material and the copper wiring caused in the multilayer wiring board needed to be prevented since it leads to moisture absorption and associated migration and dielectric breakdown. The amino group in the amino-silane coupling agent layer and the vinyl group in the low dielectric loss material are usually unlikely to form a covalent bond. Since there was observed the phenomenon that the adhesive strength was increased by increasing the thickness of the amino-silane coupling agent layer, it was assumed that that the effect of the amino-silane coupling agent layer in improving the adhesive strength was the anchor effect, i.e., formation of fine unevenness on the surface of the amino-silane coupling agent layer. That is, it was expected that almost no covalent bond, which has a strong bonding strength, is present at the interface between the amino-silane coupling agent layer and the insulating layer, and that fine interfacial peeling was likely occur due to external factors such as high temperature and high humidity.

We considered that this problem could be solved by further providing a vinyl-silane coupling agent layer on the amino-silane coupling agent layer.

According to the present invention, the adhesion strength between the copper wiring having a smooth surface and the insulating layer comprising the low dielectric loss material can be increased, and the fine peeling between the insulating layer and the copper wiring can be prevented. Furthermore, according to the present invention, the dielectric loss and conductor loss of the multilayer wiring board can be both lowered, a high-frequency multilayer wiring board having high reliability such as solder heat resistance after moisture absorption and resistance to migration can be obtained.

### BRIEF DESCRIPTION OF THE DRAWINGS

FIG. 1 is a conceptual diagram of the adhesion structure of the present invention.

FIG. 2 is an example of a pinhole produced at the adhesion interface in the structure where the amino-silane coupling agent is singly used for adhesion.

FIG. 3 is a production example of the multilayer wiring board of the present invention.

### DETAILED DESCRIPTION OF THE PREFERRED EMBODIMENTS

The present invention will be described in detail below with reference to the drawings.

The present invention relates to a multilayer wiring board having low dielectric loss and conductor loss, high moisture absorption, thermal resistance and insulation reliability, in which the copper wiring having a smooth surface and the low dielectric loss material are joined through a high adhesion interface. The present invention also relates to a copper foil, a laminate and a wiring board used for production of the multilayer wiring board of the present invention.

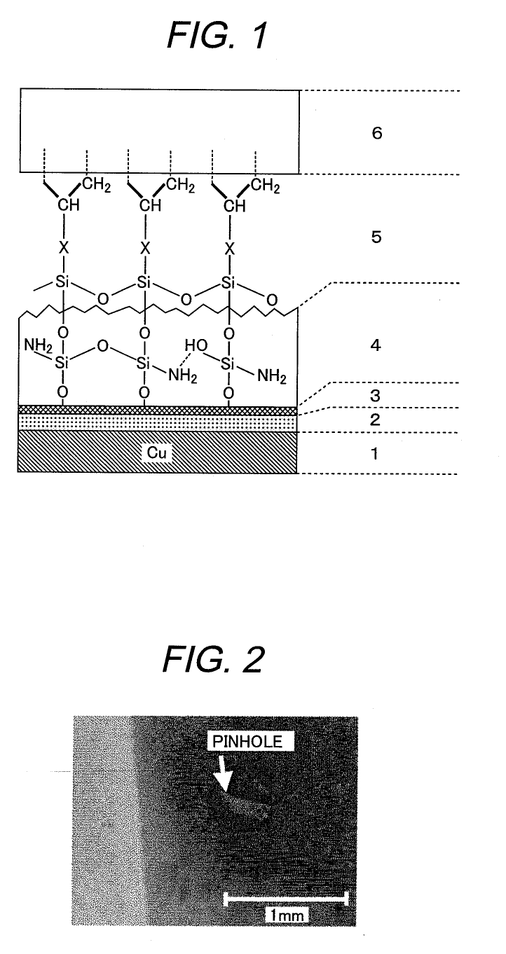

FIG. 1 schematically shows the adhesion interface structure of the present invention. An oxide or hydroxide layer 3 on a copper wiring layer 1 forms covalent bonds with silanol groups in an amino-based silane coupling agent layer 4. At this time, it is preferable that a hydroxide layer which can form a metal layer 2 of a different kind, which is more chemically stable than copper oxide, is interposed therebetween. The remaining silanol groups in the amino-silane coupling agent layer 4 form covalent bonds with silanol groups in the vinyl-silane coupling agent layer 5 formed thereon. Vinyl groups in the vinyl-silane coupling agent layer 5 form covalent bonds with vinyl groups in the low dielectric loss material layer 6. It is presumed that fine peeling at the interface can be prevented by joining the layers with covalent bonds. In addition, we thought that if fine unevenness is formed on the amino-silane coupling agent layer 4, it has a surface area larger than the copper wiring, and therefore higher adhesive strength can be obtained than in the case where the vinyl-silane coupling agent layer is provided directly on copper wiring.

The present invention is characterized by the following constitution:

(1) A multilayer wiring board of the present invention comprises a plurality of copper wiring layers, and insulating layers adhered alternately with the copper wiring layers and made of a cured product of a resin composition containing a compound having a carbon-carbon unsaturated double bond as a cross-linking component, the multilayer wiring board comprising a metal layer (A) containing one or more metallic components selected from the group consisting of tin, zinc, nickel, chromium, cobalt and aluminium on copper wiring, an oxide and/or hydroxide layer (B) of the metallic component on the metal layer (A), an amino-silane coupling agent layer (C) having an amino group in its structure on the oxide and/or hydroxide layer (B), and a vinyl-silane coupling agent layer (D) having a carbon-carbon unsaturated double bond on the amino-silane coupling agent layer (C). In the multilayer wiring board, the vinyl-silane coupling agent layer (D) includes the carbon-carbon unsaturated double bond solely or a component which forms a covalent bond with the vinyl compound in the insulating layer.

(2) The multilayer wiring board of the present invention is further characterized in that the surface roughness Ra of the copper wiring is 0.1 to 0.3 μm.

(3) The multilayer wiring board of the present invention is further characterized in that the thickness of the metal layer (A) is 1 to 100 nm; the thickness of the oxide and/or hydroxide layer (B) is 1 to 100 nm; the thickness of the amino-silane coupling agent layer (C) is 1 to 150 nm; and that the thickness of the vinyl-silane coupling agent layer having a carbon-carbon unsaturated double bond is 1 to 100 nm.

(4) The multilayer wiring board of the present invention is further characterized in that the vinyl-silane coupling agent having a carbon-carbon unsaturated double bond has any one functional group selected from a vinyl group, an acrylate group, a methacrylate group and a styrene group.

(5) The multilayer wiring board of the present invention is further characterized in that the value of the dielectric tangent of the insulating layer at 10 GHz is 0.001 to 0.006.

(6) The multilayer wiring board of the present invention is further characterized in that the insulating layer comprises a glass cloth.

(7) The multilayer wiring board of the present invention is further characterized in that the insulating layer comprises a polyphenylene ether resin having any one of an allyl group, an acrylate group, a methacrylate group and a styrene group in its structure, and a cured product of at least one cross-linking component selected from the compounds represented by formulae 1 to 4 below.

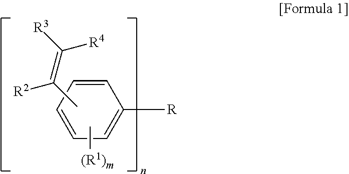

(wherein R represents a hydrocarbon skeleton, R¹ each represents the same or different hydrogen or a C₁ to C₂₀ hydrocarbon group; R², R³ and R⁴ each represents the same or different hydrogen or C₁ to C₆ hydrocarbon group; m represents an integer from 1 to 4; and n represents an integer of 2 or higher.)

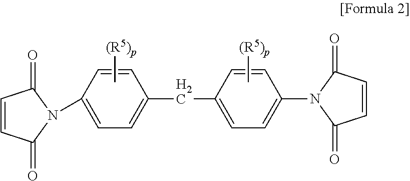

(wherein R⁵ each represents the same or different C₁ to C₄ hydrocarbon group; and p represents an integer from 1 to 4.)

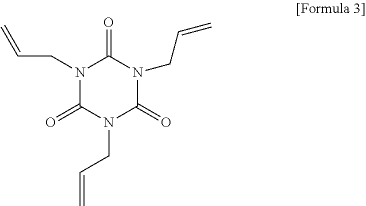

(this formula includes triallyl isocyanate or an oligomer which is its partial crosslinking product.)

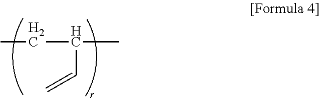

(wherein r represents an integer of 2 or higher. This formula includes polybutadiene having 90% or more of 1,2-repeating units and a number average molecular weight in terms of styrene of 1000 to 200000.)

(8) The copper foil of the present invention has a surface-treated layer on at least one surface of a copper foil having a surface roughness Ra of 0.1 to 0.3 μm, and the surface-treated layer is a copper foil characterized by having a metal layer (A) containing one or more metallic components selected from the group consisting of tin, zinc, nickel, chromium, cobalt and aluminium, an oxide and/or hydroxide layer (B) of the metallic component on the metal layer (A), an amino-silane coupling agent layer (C) having an amino group in its structure on the oxide and/or hydroxide layer (B), and a vinyl-silane coupling agent layer (D) having a carbon-carbon unsaturated double bond on the amino-silane coupling agent layer (C).

(9) The laminate of the present invention is characterized by adhering a prepreg which is a composite of a resin composition containing a compound having a carbon-carbon unsaturated double bond as a cross-linking component and a glass cloth and the surface-treated surface of the copper foil of the present invention.

(10) The wiring board of the present invention comprises a copper wiring, and an insulating layer adhered thereon and made of a cured product of a resin composition containing a compound having a carbon-carbon unsaturated double bond as a cross-linking component, the copper wiring having a surface-treated layer thereon, the surface-treated layer having a metal layer (A) containing one or more metallic components selected from tin, zinc, nickel, chromium, cobalt and aluminium, an oxide and/or hydroxide layer (B) of the metallic component on the metal layer (A), an amino-silane coupling agent layer (C) having an amino group in its structure on the oxide and/or hydroxide layer (B), and a vinyl-silane coupling agent layer (D) having a carbon-carbon unsaturated double bond on the amino-silane coupling agent layer (C). The wiring board of the present invention includes such a wiring board that has the metal layer (A), the oxide and/or hydroxide layer (B), the amino-silane coupling agent layer (C), and the vinyl-silane coupling agent layer (D) only at the interface between the insulating layer and the copper wiring. At this time, the vinyl-silane coupling agent layer (D) includes the carbon-carbon unsaturated double bond of the vinyl-silane coupling agent solely or a component which forms a covalent bond by reacting with the vinyl compound in the insulating layer.

The method for improving the adhesive strength between the copper wiring having a smooth surface and the insulating layer has been described above with reference to conventional examples. When copper is used for wiring, a copper oxide layer which is present on the copper surface is usually replaced or covered by another metal oxide layer and/or metal hydroxide layer which is more chemically stable. In addition, it is known that when an oxide layer or a hydroxide layer is present on the surface of the metal layer, the adhesive strength between the silane coupling agent layer and the metal layer increases. Although the metal oxide layer and metal hydroxide layer are also formed during surface treatment processes such as drying and cleaning, their formation may be further promoted by heating, steam-heating, chemical treatments, plasma treatments or by other means. Various metal layers and their oxide and hydroxide layers have been suggested as cladding materials for copper wiring, but application of tin, zinc, nickel, chromium, cobalt and aluminium are preferable in terms of resource circumstances, stability and workability. The metal layer can be formed by electroless plating, electroplating, substitution plating, sputtering and vacuum evaporation, among other means, on the wiring. Among them, the application of tin, zinc, nickel, chromium and cobalt are particularly preferable since they can be readily used in electroless plating and substitution plating.

The thickness of the metal layer (A) is desirably 1 to 100 nm. This is because when the thickness is 1 nm or less, the components of the metal layer (A) may diffuse within the copper wiring and disappear, while when it is more than 100 nm, the conductor loss may be disadvantageously increased due to the influence of the metal layer (A) having higher resistance than copper by the skin effect of high frequency signals. For such reasons, more preferable thickness of the metal layer (A) is 10 nm to 50 nm. Since the metal oxide layer and/or metal hydroxide layer (B) is produced by transforming the metal layer (A), they generally have a thickness of 1 nm to 100 nm. It should be noted that the metal layer (A) and the metal oxide layer and/or metal hydroxide layer (B) may contain a plurality of metal atoms.

The thickness of the amino-silane coupling agent layer (C) having an amino group in its structure is preferably 1 to 150 nm. The thickness of 1 nm is approximately the thickness of a monomolecular film. In addition, the effect of an increase in the thickness of the amine-based coupling agent layer (C) in improving the adhesive strength is only exhibited when the thickness is up to about 150 nm.

The amino-silane coupling agent layer (C) is applied onto the copper wiring as an aqueous solution. Its thickness is controlled by the concentration of the solution of the amino-silane coupling agent, and by the wiping operation after being applied. The method of applying the amino-silane coupling agent may be the dipping method, spraying method and other optional methods. The dipping time and spraying time are preferably 1 minute or longer. The copper wiring is preferably dried at a temperature ranging from 100° C. to 150° C. for 10 minutes or longer after the amino-silane coupling agent layer is formed.

The amino-silane coupling agent for use in the present invention may be any silane coupling agent as long as it has an amino group in its structure. Examples include N-2-(aminoethyl)-3-aminopropylmethyl dimethoxysilane, N-2-(aminoethyl)-3-aminopropylmethyltrimethoxysilane, N-2-(aminoethyl)-3-aminopropylmethyltriethoxysilane, 3-aminopropyltrimethoxysilane, 3-aminopropyltriethoxysilane, 3-ureidopropyltrimethoxysilane and other commercial products, and mixtures of a plurality of the amino-silane coupling agents as described in JP-T No. 2004-536220. Although amino-silane coupling agents of different structures may be used in combination, mixtures of a vinyl-silane coupling agent and an amino-silane coupling agent is undesirable since the treatment solution is very unstable and decreases workability. The amino-silane coupling agent makes a stable alkaline aqueous solution due to the interaction between an amino group and a silanol group produced by hydrolysis, but the addition of another silane coupling agent to this solution produces excessive silanol, whereby white precipitates are produced immediately.

The thickness of the vinyl-silane coupling agent layer (D) having a carbon-carbon unsaturated double bond is preferably 1 to 100 nm. Unlike the amine-based coupling agent layer, as the thickness of the vinyl-silane coupling agent layer (D) having a carbon-carbon unsaturated double bond increases, the adhesive strength tends to decrease. For this reason, more preferable thickness is, for example, 1 to 50 nm.

The vinyl-silane coupling agent layer (D) having a carbon-carbon unsaturated double bond is applied onto the wiring as an aqueous solution or alcohol solution. Its thickness is controlled by the concentration of the solution and by the wiping operation after being applied. The application method may be the dipping, spraying method or other optional means. The dipping time and spraying time are preferably 1 minute or longer. After the vinyl-silane coupling agent layer (D) having a carbon-carbon unsaturated double bond is formed, the wiring is dried at a temperature ranging from 100° C. to 150° C. for 10 minutes or longer.

The vinyl-silane coupling agent in the present invention may be any silane coupling agent having a carbon-carbon unsaturated double bond in its structure. Examples include vinyltrimethoxysilane, vinyltriethoxysilane, 3-methacryloxypropylmethyldimethoxysilane, 3-methacryloxypropyltrimethoxysilane, 3-acryloxypropyltrimethoxysilane, p-styryltrimethoxysilane and other commercial silane coupling agents. These silane coupling agents may be used in combination.

By providing the vinyl-silane coupling agent layer (D) on the amino-silane coupling agent layer (C), the adhesive strength between the copper wiring and the insulating layer of the low dielectric loss material is further increased, and the fine peeling between the copper wiring and the low dielectric loss material at a high temperature and humidity can be prevented.

In a multilayer wiring board in which the predetermined metal layer (A), the oxide and/or hydroxide layer (B) of the metal layer, the amino-silane coupling agent layer (C) and the vinyl-silane coupling agent layer (D) are provided between the copper wiring and the low dielectric loss material, the adhesive strength of 0.5 kN/m or higher, which can withstand practical use, can be maintained even on a copper wiring having a smooth surface Ra of 0.1 to 0.3 μm, and its interface is stable thermally and chemically.

The value of the dielectric tangent of the insulating layer containing the low dielectric loss material for use in the multilayer wiring board of the present invention is preferably 0.001 to 0.006 at the signal frequency used, while the value of the relative permittivity is preferably 2.5 to 4.0. The multilayer wiring board produced from the low dielectric loss material with low values of dielectric tangent and relative permittivity and the copper wiring having a smooth surface is low in both conductor loss and dielectric loss, and it therefore can reduce the transmission loss of a high frequency signal compared to conventional wiring boards.

The multilayer wiring board of the present invention may comprise a glass cloth in its insulating layer. As the glass cloth, any cloth comprising E-glass, NE-glass, D-glass, quartz glass and the like may be selected as far as the above-mentioned dielectric characteristics are allowed. In addition, it is preferable to subject the glass cloth to a surface treatment with a vinyl-silane coupling agent from the perspective of enhancing reliability and reducing dielectric tangent.

As the low dielectric loss material constituting the insulating layer of the multilayer wiring board of the present invention may be used a composite of a polyphenylene ether resin having in its structure at least one functional groups selected from an allyl group, an acrylate group, a methacrylate group and a styrene group and one or more cross-linking components selected from compounds represented by formulae 1 to 4 below. Combinations of the cross-linking components are preferably those of a polyphenylene ether resin having a terminal styrene group and a cross-linking component represented by any one of formulae 1 to 4, and more preferably those of the polyphenylene ether resin and a polyfunctional styrene compound represented by formula 1.

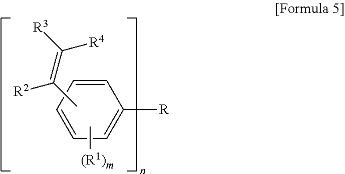

wherein R represents a hydrocarbon skeleton, which is, for example, an ethylene group, a propylene group, a butylene group, a hexylene group, a phenylene group, a polyethylene group, which is a main chain of a divinylbenzene polymer having a styrene group as a side chain, among others. R¹ each represents the same or different C₁ to C₂₀ hydrocarbon group, which is, for example, a methyl group, an ethyl group, a propyl group, a butyl group, a hexyl group, a phenyl group which may have a substituent, among others. R², R³ and R⁴ each represents the same or different hydrogen or a C₁ to C₆ hydrocarbon group, which is, for example, a methyl group, a propyl group, a butyl group, a hexyl group, a phenyl group, among others. m represents an integer from 1 to 4, and n represents an integer of 2 or higher, preferably from 2 to 8.

Examples of specific compounds include 1,2-bis(p-vinyl phenyl)ethane, 1,2-bis(m-vinylphenyl)ethane, 1-(p-vinyl phenyl)-2-(m-vinylphenyl)ethane, 1,6-bis(p-vinylphenyl)hexane, 1,4-bis(p-vinylphenylethyl)benzene, 1,4-bis(m-vinylphenylethyl)benzene, 1,3-bis(p-vinylphenylethyl)benzene, 1,3-bis(m-vinylphenylethyl)benzene, 1-(p-vinylphenylethyl)-4-(m-vinylphenylethyl)benzene, 1-(p-vinyl phenylethyl)-3-(m-vinylphenylethyl)benzene and divinylbenzene polymer (oligomer) having a styrene group as a side chain, among others, and preferably, 1,2-bis(p-vinyl phenyl)ethane, 1,2-bis(m-vinylphenyl)ethane and 1-(p-vinylphenyl)-2-(m-vinylphenyl)ethane singly or their mixtures.

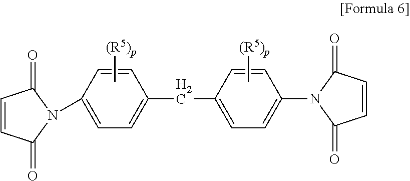

wherein R⁵ each represents the same or different C₁ to C₄ hydrocarbon group, which is, for example, a methyl group, an ethyl group, a propyl group, a butyl group, among others. p represents an integer from 1 to 4.

Examples of the compound represented by formula 2 above include bis(3-methyl-4-maleimidephenyl)methane, bis(3,5-dimethyl-4-maleimide phenyl)methane, bis(3-ethyl-4-maleimide phenyl)methane, bis(3-ethyl-5-methyl-4-maleimidephenyl)methane and bis(3-n-butyl-4-maleimidephenyl)methane, among which bis(3-ethyl-5-methyl-4-maleimidephenyl)methane is preferable.

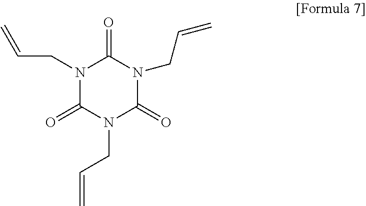

This formula includes triallyl isocyanate and an oligomer which is a partial crosslinking product thereof.

Examples of the compound represented by formula 3 above include mixtures containing 1,3,5-triallyl-1,3,5-triazine-2,4,6(1H,3H,5H)-trione and partial crosslinking products thereof, among which a mixture containing 1 to 30 wt. % of monomer components and having a number average molecular weight in terms of styrene of 1000 or lower is preferable.

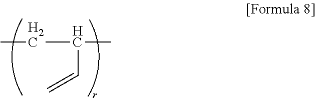

This formula includes polybutadiene having 90% or more of 1,2-repeating units and a number average molecular weight in terms of styrene of 1000 to 200000. r represents an integer of 2 or higher.

Examples of the compounds represented by formula 4 above include 1,2-polybutadiene. Examples of the compounds having a number average molecular weight in terms of styrene of 1000 to 3000 include B1000, B2000, B3000 manufactured by Nippon Soda Co., Ltd. Examples of the compounds having a number average molecular weight in terms of styrene of 100000 or higher are RB810, RB820, RB830 manufactured by JSR Corporation. These compounds may be used in combination.

Since the polyphenylene ether resin is a solid component, it improves tack-free property and other handling characteristics during production, and also improves the strength and extension of the insulating layer after being cured. In addition, the cross-linking components represented by formulae 1 to 4 are compounds having low melting points, and therefore they contribute to improving the fluidity of the low dielectric loss material in the multilayering step, and also to expressing the adhesive strength by forming covalent bonds with the vinyl-silane coupling agent layer (D) having a carbon-carbon unsaturated double bond and formed on the copper wiring. Furthermore, a silicon oxide filler may be added to the low dielectric loss material for the purpose of controlling its coefficient of thermal expansion; a flame retardant may be added for the purpose of increasing fire retardancy; and an elastomer may be added for the purpose of improving adhesive strength. The amount of each component added may be suitably determined depending on its purpose.

Subsequently, the copper foil, laminate and wiring board used for the production of the multilayer wiring board of the present invention and their production methods will be described.

The copper foil of the present invention is characterized by having the metal layer (A) containing one or more metal components selected from tin, zinc, nickel, chromium, cobalt and aluminium on at least one surface of a copper foil having a surface roughness Ra of 0.1 to 0.3 μm, the oxide and/or hydroxide layer (B) of the metallic component on the metal layer (A), the amino-silane coupling agent layer (C) having an amino group in its structure on the oxide and/or hydroxide layer (B), and the vinyl-silane coupling agent layer (D) having a carbon-carbon unsaturated double bond on the amino-silane coupling agent layer (C).

The method for treating the surface of the copper foil conforms to the method for treating the surface of the copper wiring.

The laminate of the present invention is produced by placing together a prepreg which is a composite of a low dielectric loss material containing a compound having a carbon-carbon unsaturated double bond as a cross-linking component and a glass cloth and the surface-treated surface of the copper foil of the present invention, pressurizing and heating the same to cause adhesion and curing. It is preferable to apply pressure at 1 to 5 MPa at a temperature of 180 to 230° C. for 1 to 2 hours and allow it to adhere and cure in a vacuum.

As described above, the copper foil having the treated layer of the present invention and the low dielectric loss material containing a cross-linking component having a carbon-carbon unsaturated double bond form covalent bonds therebetween via the metal layer (A), the metal oxide and/or metal hydroxide layer (B) of the same, the amino-silane coupling agent layer (C) having an amino group, and the vinyl-silane coupling agent layer (D) having a carbon-carbon unsaturated double bond. Therefore, the copper foil having a flat surface and the insulating layer comprising the low dielectric loss material can be strongly adhered.

A wiring board can be obtained by subjecting the laminate of the present invention to an etching process or other wiring processes. Mixed solutions of sulfuric acid/hydrogen peroxide, aqueous solutions of ferric chloride/hydrochloric acid and others are usable as etchants. A wiring board having a treated layer which can form a high adhesion interface on the entire surface of the copper wiring can be obtained by performing the wiring process, and then further forming on the wiring the specific metal layer (A), the metal oxide and/or metal hydroxide layer (B) of the same, the amino-silane coupling agent layer (C) having an amino group, and the vinyl-silane coupling agent layer (D) having a carbon-carbon unsaturated double bond.

The multilayer wiring board of the present invention can be obtained by multilayering and adhering the wiring board of the present invention via the prepregs of the low dielectric loss material containing a cross-linking component having a carbon-carbon unsaturated double bond. Interlayer connection can be realized by forming through-holes or brand via holes, and then applying metal plating.

### EXAMPLES

Examples and Comparative Examples will be shown below to specifically describe the present invention.

First, reagents and evaluation methods are shown.

(1) Synthesis of 1,2-bis(vinylphenyl)ethane (abbreviation: BVPE)

In a 500-ml three necked flask was placed 5.36 g (220 mmol) of granular magnesium (manufactured by Kanto Chemical Co., Inc.) for Grignard reaction. A dropping funnel, a nitrogen introducing pipe and a septum cap were attached to the flask. Under a stream of nitrogen, the entire system was dehydrated with heating while the magnesium grains were stirred with a stirrer. 300 ml of dried tetrahydrofuran was placed in a syringe, and was injected into the flask through the septum cap. After the solution was cooled to −5° C., 30.5 g (200 mmol) of vinylbenzyl chloride (manufactured by Tokyo Chemical Industry Co., Ltd.) was added dropwise over 4 hours using the dropping funnel. Stirring was continued at 0° C. for 20 hours after the completion of dropping.

After the completion of the reaction, the reaction solution was filtrated to remove the residual magnesium, and was concentrated by an evaporator. The concentrated solution was diluted with hexane, washed once with a 3.6% aqueous solution of hydrochloric acid and three times with pure water, and was then dehydrated with magnesium sulfate. The dehydrated solution was purified by running it through a short column of silica gel (Wako gel C300 manufactured by Wako Pure Chemical Industries, Ltd.)/hexane, and was finally vacuum-dried, giving target BVPE. The resultant BVPE was a mixture of 1,2-bis(p-vinylphenyl)ethane (PP component, solid), 1,2-bis(m-vinylphenyl)ethane (mm component, liquid) and 1-(p-vinylphenyl)-2-(m-vinylphenyl)ethane (mp component, liquid), and the yield was 90%.

Examination of the structure by ¹H-NMR revealed the agreement with a literature value (6H-vinyl: α-2H (6.7), β-4H (5.7, 5.2); 8H-aromatic (7.1 to 7.4); 4H-methylene (2.9)). The resultant BVPE was used as a cross-linking component.

(2) Synthesis of thermosetting polyphenylene ether (abbreviation: APPE)

Into a two-necked flask with a stirring bar placed therein were added Di-μ-hydroxo bis[(N,N,N′,N′-tetramethylethylenediamine)copper (II)]dichloride: 0.464 g (1.0 mmol), water: 4 ml, and tetramethylethylenediamine: 1 ml, and the mixture was stirred. After the stirring was stopped, a solution of 2-allyl-6-methylphenol: 1.34 g (9.0 mmol) and 2,6-dimethylphenol: 9.90 g (81.0 mmol) in toluene: 50 ml was gently added to the flask, and the mixture was stirred at 500 to 800 rpm under an oxygen atmosphere of 40 ml/min. or 50 ml/min. The mixture was stirred under an oxygen atmosphere for 6 hours.

After the completion of the reaction, the reaction system was precipitated into a large excess of hydrochloric acid/methanol. The precipitates were washed with methanol, and then dissolved in toluene to filter off insoluble matters. The insoluble matters were dissolved in toluene again, and was precipitated into a large excess of hydrochloric acid/methanol. The precipitates were washed with methanol, and then vacuum-dried at 120° C./2 hours and 150° C./30 minutes, giving a white solid matter. The molecular weight and molecular weight distribution of the solid matter were Mn=15000 and Mw/Mn=1.7, respectively.

(3) Other reagents

Thermosetting polyphenylene ether (2): OPE2St, number average molecular weight in terms of styrene: 2200, containing a terminal styrene group, manufactured by Mitsubishi Gas Chemical Company, Inc.
bismaleimide: BMI-5100,
3,3′-dimethyl-5,5′-diethyl-4,4′-diphenylmethane bismaleimide, manufactured by Daiwa Kasei Co., Ltd.

High-molecular-weight polybutadiene: RB810, number average molecular weight in terms of styrene: 130000, 1,2-binding: 90% or higher, manufactured by JSR Corporation

Low-molecular-weight polybutadiene: B3000, number average molecular weight in terms of styrene: 3000, 1,2-bond content: 90% or higher, manufactured by Nippon Soda Co., Ltd.
TAIC: triallyl isocyanate, manufactured by Wako Pure Chemical Industries, Ltd.

### Hydrogenated Styrene Butadiene Copolymer:

TAFTEC (registered trademark) H1052, styrene content: 20 wt. %, Mn72000, breaking elongation: 700%, manufactured by Asahi Kasei Chemicals Corporation

### Curing Catalyst:

2,5-dimethyl-2,5-di-t-butylperoxidehexyne-3 (abbreviation: 25B), manufactured by NOF CORPORATION
Flame retardant: SAYTEX8010, 1,2-bis(pentabromophenyl)ethane, mean particle diameter: 1.5 μm, manufactured by Albemarle Japan Corporation

Silicon oxide filler: Admafine, Mean particle diameter: 0.5 μm, manufactured by Admatechs Co., Ltd.

### Vinyl-Silane Coupling Agent:

1) KBM-1003, vinyl methoxysilane, manufactured by Shin-Etsu Chemical

2) KBM-50 3,3-methacryloxypropyltrimethoxysilane, manufactured by Shin-Etsu Chemical

3) KBM-1043, p-styryltrimethoxysilane, Shin-Etsu Chemical Amino-silane coupling agent:

1) KBM-603:N-2-(aminoethyl)-3-aminopropyltrimethoxysilane, Shin-Etsu Chemical

2) KBM-903: 3-aminopropyltrimethoxysilane, Shin-Etsu Chemical

3) KBE-585: 3-ureidopropyltriethoxysilane, Shin-Etsu Chemical

### Copper Foils:

1) JTC foil, thickness: 35 μm, Ra≈0.2 μm, manufactured by Nikko Materials Corp.

2) Secure HFZ foil, thickness: 35 μm, substitution tin plated/amino silanized, Ra≈0.2 μm, manufactured by Atotech Japan K.K.

Glass cloths: 1) t 100 μm, quartz glass cloth, manufactured by Shin-Etsu Quartz Products Co., Ltd.

2) t≈100 μm, E glass cloth, manufactured by Nitto Boseki Co., Ltd.

(4) Surface treatment of copper foil: A JTC foil was subjected to substitution tinning using a UTB580-Z18 substitution tin plating solution manufactured by Ishihara Chemical Co., Ltd. The processing conditions are shown below. The JTC foil was soaked in a 10 wt. % aqueous solution of sulfuric acid at 20° C. for 15 seconds, and then washed with a stream of water for 1 minute. The JTC foil after being washed was soaked in a substitution tin plating solution heated to 60° C. for 5 minutes to subject it to substitution tinning. The foil was then washed with running water for 1 minute and dried at 120° C./1 hour. Observation of a cross section of the copper foil revealed that the thickness of substitution tinning was about 100 nm (refer to FIG. 2). The surface roughness Ra was 0.2 μm. In addition, the surface analysis by XPS confirmed that a few nanometers of a layer containing tin oxide and tin hydroxide was present on the surface of the tin layer.

An aqueous solution of an amino-silane coupling agent having a predetermined concentration was applied onto the JTC foil with substitution tin plating formed thereon by the dipping method, and the foil was dried at 120° C./1 hour to form an amino-silane coupling agent layer. Subsequently, a solution of a vinyl-silane coupling agent having a predetermined concentration was prepared by using a 50 wt. % aqueous solution of methanol as a solvent. Various copper foils were soaked in the vinyl-silane coupling treatment solution for 1 minute, and dried under the condition of 120° C./1 hour to prepare treated copper foils having a vinyl-silane coupling agent layer on their outermost surfaces.

(5) Measurement of thickness of coupling treatment layer

A polyimide tape was adhered on a glass substrate to mask a part thereof. The glass substrate was soaked in coupling treating solutions having various concentrations for 1 minute, and was then dried under the condition of 120° C./1 hour. The polyimide tape on the glass substrate was peeled off, and the difference in height of the surfaces with and without the coupling treatment agent applied was measured by using a stylus surface profiler, DEKTAK 8, manufactured by ULVAC, Inc.

(6) Surface treatment of glass cloth

A glass cloth was soaked in a 0.5 wt. % solution of KBM503 methanol for 1 hour. The glass cloth was then removed from the methanol solution, and was dried in air with heating at 100° C./30 minutes to subject the glass cloth to a surface treatment.

(7) Method for preparing varnish

A predetermined amount of a coupling agent and a filler were stirred in a methyl ethyl ketone solution with a ball mill for 2 hours to subject the filler to a coupling treatment. Subsequently, predetermined amounts of a resin material, a flame retardant, a curing catalyst and toluene were added thereto and stirring was continued for about 8 hours until the resin component were completely dissolved to prepare a varnish. The concentration of the varnish was 45 to 65 wt. %

(8) Method for preparing prepregs

After the glass cloth was soaked in the above-mentioned varnish, the glass cloth was lifted vertically at a constant speed through a slit having a predetermined gap, and was then dried to prepare a prepreg. The amount of the resin applied was adjusted by the gap of the slit. The drying condition was 100° C./10 minutes.

(9) Method for preparing copper-clad laminate

Four prepregs prepared by the above method were laminated, and each of the copper foils which had been variously treated was placed thereon. The laminate was pressurized and heated to be cured by vacuum pressing. The curing conditions were such that the laminate was pressed under 3 MPa from room temperature and the temperature was elevated at a constant rate (6° C./min.) to 200° C. at which the laminate was then held for 60 minutes.

(10) Measurement of relative permittivity and dielectric tangent

By a cavity resonance method using 8722ES type network analyzer manufactured by Agilent Technology Inc. and a cavity resonator manufactured by Kantoh Electronics Application and Development Inc., the relative permittivity and dielectric tangent were measured at 10 GHz. The copper clad laminate was subjected to removing the copper foil by etching, and was cut into apiece of 1.0 mm×80 mm. A sample prepared from the resin plate was cut into a piece of 1.0×1.5×80 mm.

(11) Measurement of peel strength

Peel strength was measured according to Japanese Industrial Standard (JIS C6481). The copper-clad laminate prepared in (9) was used as a sample.

(12) PCT resistance (resistance to high temperature, humidity and pressure)

The copper-clad laminate of (9) was cut into a 5 cm×5 cm piece, and was left to stand at 121° C., 2 atmospheric pressures and under a saturated steam for 24 hours. The laminate was then cooled. The copper foil was peeled off from the laminate to observe the tin layer on the copper foil. Those samples found to have peeling or pinholes generated on tin layer were judged to have fine peeling.

The constitutions and characteristics of Examples and Comparative Examples will be described below.

Table 1 shows the constitutions and basic characteristics of the prepregs containing a low dielectric loss material. Prepreg 1 is a prepreg containing TRIC as a cross-linking component; prepreg 2 is a prepreg containing bismaleimide as a cross-linking component; prepreg 3 is a prepreg containing polybutadiene as a cross-linking component; prepreg 4 is a prepreg containing BVPE as a cross-linking component; and prepreg 5 is an example of prepregs containing BVPE as a cross-linking component with the glass cloth being quartz glass. The cured product of each prepreg has low relative permittivity and dielectric tangent, and particularly the performance of prepreg 5 using the glass cloth made of quartz is good.

TABLE 1

| Resin name | | Prepreg 1 | Prepreg 2 | Prepreg 3 | Prepreg 4 | Prepreg 5 |
|---|---|---|---|---|---|---|
| Cross-linking component | TAIC | 16 | 0 | 0 | 0 | 0 |
| | BMI-5100 | 0 | 16 | 0 | 0 | 0 |
| | BVPE | 0 | 0 | 0 | 16 | 16 |
| | OPE2St | 0 | 39 | 0 | 39 | 39 |
| | APPE | 49 | 0 | 0 | 0 | 0 |
| | RB810 | 0 | 0 | 14 | 0 | 0 |
| | B3000 | 0 | 0 | 41 | 0 | 0 |
| High-molecular weight component | H1052 | 0 | 10 | 10 | 10 | 10 |
| Polymerization initiator | 25B | 2.8 | 2.8 | 2.8 | 2.8 | 2.8 |
| Filler | Admafine | 20 | 20 | 20 | 20 | 20 |
| Coupling treatment agent | KBM-503 | 0.2 | 0.2 | 0.2 | 0.2 | 0.2 |
| Flame retardant | SAYTEX8010 | 12 | 12 | 12 | 12 | 12 |
| Glass cloth type | | E-glass | E-glass | E-glass | E-glass | Quartz glass |
| Resin content in prepreg | wt % | 55 | 55 | 55 | 55 | 55 |
| Relative dielectric constant of cured prepreg | at 10 GHz | 3.5 | 3.4 | 3.4 | 3.4 | 2.9 |
| Dielectric tangent of cured prepreg | at 10 GHz | 0.005 | 0.005 | 0.004 | 0.004 | 0.001 |

### Comparative Examples 1 to 3

JTC foils which were subjected to substitution tinning were subjected to various amino-silane coupling treatments only, and their adhesive strength for prepreg 1 was determine. The results are shown at Comparative Examples 1 to 3 in Table 2. The peel strength of the untreated product is 0.2 kN/m, while the peel strength when it was subjected to the amino-silane coupling treatment was 0.75 kN/m at the highest. It was confirmed that the amino-silane coupling treatment is effective in improving the adhesive strength between the low dielectric loss material containing the cross-linking component having a carbon-carbon unsaturated double bond and the copper foil having a smooth surface. It was also shown that the concentration of the amino-silane coupling treatment is preferably 6 wt. % or lower and more preferably 4 wt. % or lower, while the thickness is preferably 200 nm or less and more preferably 150 nm or less. However, in Comparative Examples 1 to 3 which were subjected to the amino-silane coupling treatment only, fine peeling was generated between the JTC foil and the low dielectric loss material, and many pinholes, which were produced by partial dissolving of the tin, tin oxide and tin hydroxide layers, were observed at the interface. An example of the pinholes generated between the JTC foil and the low dielectric loss material is shown in FIG. 2. Although the amino-silane coupling treatment increases peel strength, PCT resistance, that is, stability to high temperature, humidity and pressure conditions needed to be improved.

### Comparative Example 4

A JTC foil which was subjected to substitution tinning was treated with KBM-1043 as a vinyl-silane coupling agent. Evaluation results of the adhesive strength for prepreg 1 are shown at Comparative Example 4 in Table 2. The vinyl-silane coupling agent was expected to be highly effective in improving adhesive strength since it can form covalent bonds directly with the cross-linking component contained in the low dielectric loss material. However, in spite that its PCT resistance was improved, its peel strength was lower than that of the amino-silane coupling agent, and its effects in improving peel strength by an increase in the thickness was not found. Improvement of peel strength was an object for the vinyl-silane coupling process.

### Comparative Example 5

A treatment using a mixed solution of the amino-silane coupling agent and the vinyl-silane coupling agent was attempted. The results are shown at Comparative Example 5 in Table 2. When the both agents were mixed in a 50 wt. % aqueous solution of methanol, white precipitates were produced immediately and therefore the solution could not be applied onto the JTC foil. It was found that the mixed solution of the amino-silane coupling agent and the vinyl-silane coupling agent was unstable so that it could not withstand practical use.

TABLE 2

| | | Conditions and characteristics of amine-based | | | |
|---|---|---|---|---|---|
| | | silane coupling agent treatment | | | |
| | | Type and | Thickness of | | |
| | | treatment | silane-treated | Peel | Presence |
| Copper | | concentration | layer | stength | of line |
| foil | No. | (wt %) | (μm) | (kN/m) | peeling |
| JTC foil | Comp. Ex. 1 | KBM-603 | | | |
| with | | 0 | 0 | 0.2 | Yes |
| substitution | | 0.2 | 0.001~0.03 | 0.59 | Yes |
| tin | | 2 | 0.03~0.10 | 0.66 | Yes |
| plating | | 4 | 0.10~0.15 | 0.73 | Yes |
| | | 6 | 0.15~0.20 | 0.55 | Yes |
| | | 8 | 0.20~0.30 | 0.18 | Yes |
| | Comp. Ex. 2 | KBM-903 | | | |
| | | 0.2 | 0.001~0.03 | 0.51 | Yes |
| | | 2 | 0.03~0.10 | 0.59 | Yes |
| | | 4 | 0.10~0.15 | 0.62 | Yes |
| | | 6 | 0.15~0.20 | 0.49 | Yes |
| | | 8 | 0.20~0.30 | 0.15 | Yes |
| | Comp. Ex. 3 | KBE-585 | | | |
| | | 0.2 | 0.001~0.03 | 0.58 | Yes |
| | | 2 | 0.03~0.10 | 0.68 | Yes |
| | | 4 | 0.10~0.15 | 0.75 | Yes |
| | | 6 | 0.15~0.20 | 0.56 | Yes |
| | | 8 | 0.20~0.30 | 0.2 | Yes |
| | Comp. Ex. 4 | KBM-1043 | | | |
| | | 0.2 | 0.001~0.01 | 0.5 | No |
| | | 0.5 | 0.01~0.03 | 0.46 | No |
| | | 1 | 0.04~0.06 | 0.49 | No |
| | | 2 | 0.07~0.100 | 0.48 | No |
| | | 4 | 0.100~0.170 | 0.34 | No |

| Comp. Ex. 5 | Mixed solution of KBM-1043/KBM-603 | |
|---|---|---|
| | 0.2/0.2 | Immeasurable due to generation of precipitates |

### Examples 1 to 4

In Examples 1 to 4, copper foils with KBM-1043 applied as a vinyl-silane coupling agent on the amino-silane coupling agent layer of Comparative Example 1 were used to examine the effects of the multilayered silane coupling agent layers. The evaluation results of the adhesive strength for prepreg 1 are shown in Table 3. In Examples 1 to 4 using the multilayered silane coupling agent layers, the PCT resistance was improved. The values of their peel strength exhibited were higher than in the case where the amino-silane coupling agent layer or vinyl-silane coupling agent layer was singly used. The above results reasonably indicate that it is possible to obtain a copper-clad laminate, wiring board, and multilayer wiring board which are low both in dielectric loss and conductor loss, high in adhesive strength, and excellent in PCT resistance by providing the amino-silane coupling agent layer and the vinyl-silane coupling agent layer at the joining interface between the copper wiring and the low dielectric loss material.

TABLE 3

| | | Treatment | Vinyl-based | | | |
|---|---|---|---|---|---|---|
| | | concentration of | silane coupling agent | | | |
| | | amine-based silane | Treatment | | | |
| | | coupling agent | concentration | Thickness | Peel strength | Presence of |
| Copper foil | No. | (wt %) | (wt %) | (μm) | (kN/m) | fine peeling |
| JTC | Ex. 1 | KBM-603 | KBM-1043 | | | |
| foil | | 0.2 | 0.2 | 0.001~0.01 | 0.77 | No |
| with | | 0.2 | 0.5 | 0.01~0.03 | 0.74 | No |
| substitution | | 0.2 | 1 | 0.04~0.06 | 0.76 | No |
| tin | | 0.2 | 2 | 0.07~0.10 | 0.69 | No |
| plating | | 0.2 | 4 | 0.10~0.17 | 0.58 | No |
| | Ex. 2 | 2 | 0.2 | 0.001~0.01 | 0.79 | No |
| | | 2 | 0.5 | 0.01~0.03 | 0.78 | No |
| | | 2 | 1 | 0.04~0.06 | 0.77 | No |
| | | 2 | 2 | 0.07~0.10 | 0.72 | No |
| | | 2 | 4 | 0.10~0.17 | 0.7 | No |
| | Ex. 3 | 4 | 0.2 | 0.001~0.01 | 0.72 | No |
| | | 4 | 0.5 | 0.01~0.03 | 0.75 | No |
| | | 4 | 1 | 0.04~0.06 | 0.76 | No |
| | | 4 | 2 | 0.07~0.10 | 0.7 | No |
| | | 4 | 4 | 0.10~0.17 | 0.65 | No |
| | Ex. 4 | 8 | 0.2 | 0.001~0.01 | 0.72 | No |
| | | 8 | 0.5 | 0.01~0.03 | 0.76 | No |
| | | 8 | 1 | 0.04~0.06 | 0.76 | No |
| | | 8 | 2 | 0.07~0.10 | 0.72 | No |
| | | 8 | 4 | 0.10~0.17 | 0.68 | No |

### Examples 5 to 8

In Examples 5 to 8, copper foils with KBM-503 applied as the vinyl-silane coupling agent on the amino-silane coupling agent layer of Comparative Example 2 were used to examine the effects of the multilayered silane coupling agent layers. The evaluation results of the adhesive strength for prepreg 1 are shown in Table 4. In Examples 5 to 8 using the multilayered silane coupling agent layers, PCT resistance was improved. In addition, the values of the peel strength exhibited were high at the treatment concentration of the amino-silane coupling agent of 4 wt. % or lower and the treatment concentration of the vinyl-silane coupling agent of 1 wt. % or lower. The above results reasonably indicate that it is possible to obtain a copper-clad laminate, wiring board, and multilayer wiring board which are low in both dielectric loss and conductor loss, high in adhesive strength, and excellent in PCT resistance by providing the amino-silane coupling agent layer and vinyl-silane coupling agent layer at the joining interface between the copper wiring and the low dielectric loss material.

TABLE 4

| | | Treatment | Vinyl-based | | | |
|---|---|---|---|---|---|---|
| | | concentration of | silane coupling agent | | | |
| | | amine-based silane | Treatment | | | |
| | | coupling agent | concentration | Thickness | Peel strength | Presence of |
| Copper foil | No. | (wt %) | (wt %) | (μm) | (kN/m) | fine peeling |
| JTC | Ex. 5 | KBM-903 | KBM-503 | | | |
| foil | | 0.2 | 0.2 | 0.001~0.01 | 0.66 | No |
| with | | 0.2 | 0.5 | 0.01~0.03 | 0.63 | No |
| substitution | | 0.2 | 1 | 0.04~0.06 | 0.57 | No |
| tin | | 0.2 | 2 | 0.07~0.10 | 0.59 | No |
| plating | Ex. 6 | 2 | 0.2 | 0.001~0.01 | 0.64 | No |
| | | 2 | 0.5 | 0.01~0.03 | 0.63 | No |
| | | 2 | 1 | 0.04~0.06 | 0.56 | No |
| | | 2 | 2 | 0.07~0.10 | 0.37 | No |
| | Ex. 7 | 4 | 0.2 | 0.001~0.01 | 0.62 | No |
| | | 4 | 0.5 | 0.01~0.03 | 0.63 | No |
| | | 4 | 1 | 0.04~0.06 | 0.55 | No |
| | | 4 | 2 | 0.07~0.10 | 0.41 | No |
| | Ex. 8 | 8 | 0.2 | 0.001~0.01 | 0.58 | No |
| | | 8 | 0.5 | 0.01~0.03 | 0.54 | No |
| | | 8 | 1 | 0.04~0.06 | 0.41 | No |
| | | 8 | 2 | 0.07~0.10 | 0.42 | No |

### Examples 9 to 12

In Examples 9 to 12, copper foils with KBM-1003 applied as the vinyl-silane coupling agent on the amino-silane coupling agent layer of Comparative Example 3 were used to examine the effects of the multilayered silane coupling agent layers. The evaluation results of the adhesive strength for prepreg 1 are shown in Table 5. In Examples 9 to 12 using the multilayered silane coupling agent layers, PCT resistance was improved. In addition, the values of the peel strength exhibited were high at the treatment concentration of the amino-silane coupling agent of 4 wt. % or lower and the treatment concentration of the vinyl-silane coupling agent of 1 wt. % or lower. The above results reasonably indicate that it is possible to obtain a copper-clad laminate, wiring board, and multilayer wiring board which are low in both dielectric loss and conductor loss, high in adhesive strength, and excellent in PCT resistance by providing the amino-silane coupling agent layer and the vinyl-silane coupling agent layer at the joining interface between the copper wiring and the low dielectric loss material.

TABLE 5

| | | Treatment | Vinyl-based | | | |
|---|---|---|---|---|---|---|
| | | concentration of | silane coupling agent | | | |
| | | amine-based silane | Treatment | | | |
| | | coupling agent | concentration | Thickness | Peel strength | Presence of |
| Copper foil | No. | (wt %) | (wt %) | (μm) | (kN/m) | fine peeling |
| JTC | Ex. 9 | KBE-585 | KBM-1003 | | | |
| foil | | 0.2 | 0.2 | 0.001~0.01 | 0.6 | No |
| with | | 0.2 | 0.5 | 0.01~0.03 | 0.6 | No |
| substitution | | 0.2 | 1 | 0.04~0.06 | 0.55 | No |
| tin | | 0.2 | 2 | 0.07~0.10 | 0.3 | No |
| plating | Ex. 10 | 2 | 0.2 | 0.001~0.01 | 0.68 | No |
| | | 2 | 0.5 | 0.01~0.03 | 0.65 | No |
| | | 2 | 1 | 0.04~0.06 | 0.62 | No |
| | | 2 | 2 | 0.07~0.10 | 0.43 | No |
| | Ex. 11 | 4 | 0.2 | 0.001~0.01 | 0.75 | No |
| | | 4 | 0.5 | 0.01~0.03 | 0.71 | No |
| | | 4 | 1 | 0.04~0.06 | 0.7 | No |
| | | 4 | 2 | 0.07~0.10 | 0.49 | No |
| | Ex. 12 | 8 | 0.2 | 0.001~0.01 | 0.54 | No |
| | | 8 | 0.5 | 0.01~0.03 | 0.52 | No |
| | | 8 | 1 | 0.04~0.06 | 0.4 | No |
| | | 8 | 2 | 0.07~0.10 | 0.33 | No |

### Examples 13 to 16

In Examples 13 to 16, the adhesiveness for prepregs 2 to 5 containing a treated copper foil which is similar to that in Example land various cross-linking components were examined. The results are shown in Table 6. The adhesion between prepregs having various cross-linking components and the copper foil having the multilayered silane coupling treating layer was good, and generation of fine peeling was not found. The above results reasonably indicates that it is possible to obtain a copper-clad a laminate, a wiring board, and a multilayer wiring board which are low in both dielectric loss and conductor loss high in adhesive strength, and excellent in PCT resistance by providing the amino-silane coupling agent layer and the vinyl-silane coupling agent layer at the joining interface between the copper wiring and the low dielectric loss material.

TABLE 6

| | | | Treatment concentration of | | Peel strength | Presence of |
|---|---|---|---|---|---|---|
| Copper foil | No. | Prepreg type | silane coupling agent (wt %) | | (kN/m) | fine peeling |
| JTC | Ex. 13 | Prepreg 2 | KBM-603 | KBM-1043 | — | — |
| foil | | | 0.2 | 0.2 | 0.64 | No |
| with | | | 0.2 | 0.5 | 0.64 | No |
| substitution | | | 0.2 | 1 | 0.6 | No |
| tin | | | 0.2 | 2 | 0.61 | No |
| plating | Ex. 14 | Prepreg 3 | 0.2 | 0.2 | 0.78 | No |
| | | | 0.2 | 0.5 | 0.76 | No |
| | | | 0.2 | 1 | 0.76 | No |
| | | | 0.2 | 2 | 0.75 | No |
| | Ex. 15 | Prepreg 4 | 0.2 | 0.2 | 0.7 | No |
| | | | 0.2 | 0.5 | 0.69 | No |
| | | | 0.2 | 1 | 0.65 | No |
| | | | 0.2 | 2 | 0.65 | No |
| | Ex. 16 | Prepreg 5 | 0.2 | 0.2 | 0.69 | No |
| | | | 0.2 | 0.5 | 0.67 | No |
| | | | 0.2 | 1 | 0.64 | No |
| | | | 0.2 | 2 | 0.65 | No |

### Example 17

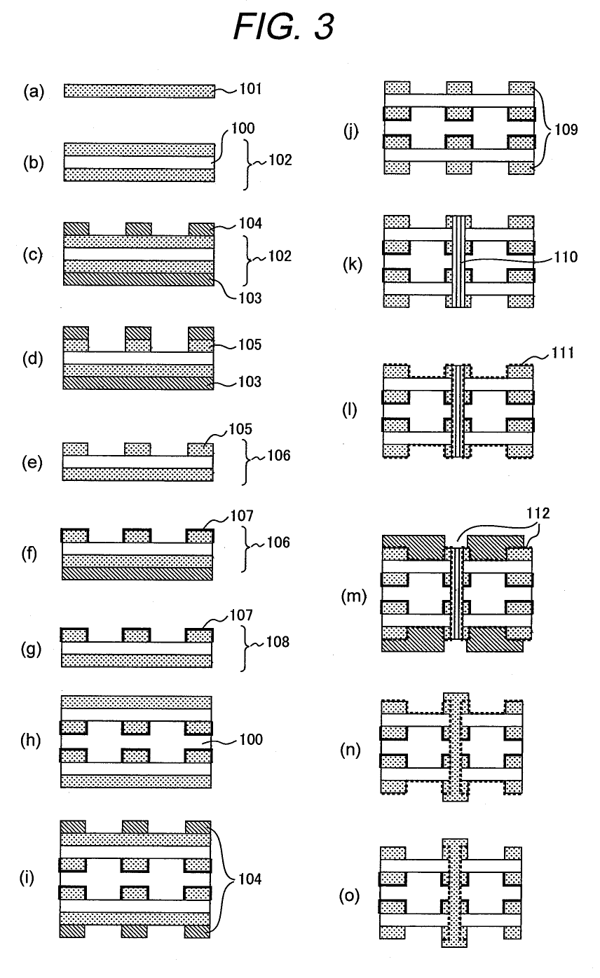

A multilayer wiring board was produced in Example 17. The procedure is shown in FIG. 3.

(A) Secure HFZ foil was soaked in a 0.2 wt. % KBM-1043 solution for 1 minute, and was then dried at 120° C. for 1 hour, producing a treated copper foil 101.

(B) Prepreg 100 used in Example 1 was placed between two treated copper foils 101, heated at a programming rate of 6° C./min. while being pressurized in a vacuum to 3 MPa, and maintained at 200° C. for 60 minutes to produce a double-sided copper-clad laminate 102.

(C) A photoresist (HS425 manufactured by Hitachi Chemical Co., Ltd.) was laminated on one side of the double-sided copper-clad laminate 102, and was flood-exposed to deposit a mask 103. Subsequently, a photoresist (HS425 manufactured by Hitachi Chemical Co., Ltd.) was laminated on the remaining copper surface. A test pattern 104 was exposed, and unexposed portions of the photoresist were developed with a 1% sodium carbonate solution.

(D) The exposed copper foil was removed by etching with an etchant containing 5% of sulfuric acid and 5% of hydrogen peroxide, forming a copper wiring 105 on one side of the double-sided copper-clad laminate.

(E) The remaining photoresist was removed by a 3% sodium hydroxide solution, giving a wiring board 106 having a wiring on one side thereof.

(F) A photoresist (HS425 manufactured by Hitachi Chemical Co., Ltd.) was laminated on the side of the wiring board 106 without the wiring, and was flood-exposed. Subsequently, a substitution tin plating layer was formed on the copper wiring 105 in a manner similar to the preceding Example. Furthermore, the wiring board 106 was soaked in a 2 wt. % aqueous solution of KBM-603 for 1 minute, and was dried at 120° C. for 1 hour to form an amino-silane coupling agent layer. The wiring board 106 was then soaked in a 0.2 wt. % solution of KBM-1043 containing a 50 wt. % aqueous solution of methanol as a solvent for 1 minute, and was dried at 120° C. for 1 hour, producing a surface treated wiring 107 with a vinyl-silane coupling agent layer formed thereon.

(G) The remaining photoresist was removed with a 3% solution of sodium hydroxide, washed with water and dried to give a wiring board 108 having the surface treated wiring 107 on one side thereof. Two wiring boards were produced in a similar manner.

(H) The wiring sides of the two wiring boards were placed together, and the prepreg 100 was inserted therebetween. The laminate was heated and pressured in a vacuum to form multilayers. The heating condition was 200° C./60 min., and the pressure was 3 MPa.

(I) A photoresist (HS425 manufactured by Hitachi Chemical Co., Ltd.) was laminated on the outer layer of the multilayered wiring board and a test pattern was exposed. Unexposed portions of the photoresist were developed with a 1% sodium carbonate solution.

(J) The exposed copper foil was removed by etching with an etchant containing 5% of sulfuric acid and 5% of hydrogen peroxide, and the remaining photoresist was removed with a 3% solution of sodium hydroxide to form an outer layer wiring 109.

(K) A through-hole 110 which connects the inner layer wiring and external wiring was formed by drilling.

(L) The wiring board was soaked in a colloidal solution of the metal plating catalyst to apply the catalyst inside the through-hole and onto the surface of the substrate. After the activation treatment of the plating catalyst, an about 1-μm thick seed film 11 was formed by means of the electroless plating (CUST2000 manufactured by Hitachi Chemical Co., Ltd.).

(M) A sheet of a photoresist (HN920 manufactured by Hitachi Chemical Co., Ltd.) was laminated on both surfaces of the wiring board. The through-hole portions and the end portions of the wiring board were masked and the board was exposed, and thereafter developed with a 3% sodium carbonate solution to provide an opening portion 112.

(N) Electrodes were provided at the end portions of the wiring board, and the through portions were plated with copper in a thickness of about 18 μm by the electrolytic plating. Thereafter, electrode portions were cut and removed, and the residual photoresist was removed by use of a 5% sodium hydroxide aqueous solution.

(O) The wiring board was soaked in the etching solution containing sulfuric acid in 5% and hydrogen peroxide in 5%, and the etching of an about 1 μm thickness was performed to remove the seed film; thus a multilayer wiring board was produced. No broken wire or peeling of wiring occurred was generated in this multilayer wiring board during the multilayering process. Further, since this multilayer substrate has low relative permittivity and dielectric tangent of the insulating material and its wiring surface is smooth, it is low in both dielectric loss and conductor loss, and is suitable for multilayer wiring boards of high-frequency devices.

The copper foil, laminate, wiring board, and multilayer wiring board of the present invention is low in dielectric loss and conductor loss and high in adhesive strength, and therefore they are suitable as materials of wiring boards for high-frequency-compatible electronic devices such as high-speed servers, routers, millimeter wavelength radars.

What is claimed is:

1. A wiring board comprising a copper wiring, and an insulating layer which is a cured product of a resin composition containing a compound having a carbon-carbon unsaturated double bond as a cross-linking component,
the wiring board having a surface-treated layer formed on one or both sides of the copper wiring, and
the surface-treated layer having a metal layer (A) containing at least one metallic component selected from the group consisting of tin, zinc, nickel, chromium, cobalt and aluminium,
an oxide and/or hydroxide layer (B) of the metallic component on the metal layer (A),
an amino-silane coupling agent layer (C) having an amino group in its structure on the oxide and/or hydroxide layer (B), and
a vinyl-silane coupling agent layer (D) having a carbon-carbon unsaturated double bond on the amino-silane coupling agent layer (C).

2. The wiring board according to claim 1,
wherein the surface roughness Ra of the surface of the copper wiring is 0.1 to 0.3 μm.

3. The wiring board according to claim 1,
wherein the thickness of the metal layer (A) is 1 to 100 nm, the thickness of the oxide and/or hydroxide layer (B) is 1 to 100 nm, the thickness of the amino-silane coupling agent layer (C) is 1 to 150 nm, and the thickness of the vinyl-silane coupling agent layer having a carbon-carbon unsaturated double bond is 1 to 100 nm.

4. The wiring board according to claim 1,
wherein the vinyl-silane coupling agent having a carbon-carbon unsaturated double bond has any one functional group selected from the group consisting of a vinyl group, an acrylate group, a methacrylate group and a and styrene group.

5. The wiring board according to claim 1,
wherein the dielectric tangent value of the insulating layer at 10 GHz is 0.001 to 0.006.

6. The wiring board according to claim 1,
wherein the insulating layer comprises a glass cloth.

7. The wiring board according to claim 1,
wherein the insulating layer contains a modified polyphenylene ether resin having any one group selected from the group consisting of an allyl group, an acrylate group, a methacrylate group and styrene group in its structure, and
a cured product of at least one cross-linking component selected from the group consisting of compounds represented by formulae 1 to 4 below. 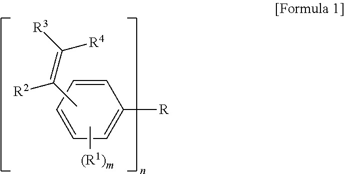
(wherein R represents a hydrocarbon skeleton, R¹ each represents the same or different C₁ to C₂₀ hydrocarbon group, R², R³ and R⁴ each represents the same or different hydrogen or a C₁ to C₆ hydrocarbon group, m represents an integer from 1 to 4; and n represents an integer of 2 or higher.) 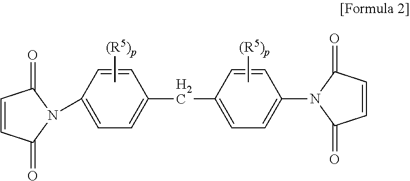
(wherein R⁵ each represents the same or different C₁ to C₄ hydrocarbon group; and p represents an integer from 1 to 4.) 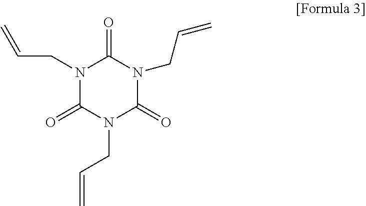
(this formula includes triallyl isocyanate or an oligomer which is its partial crosslinking product.) 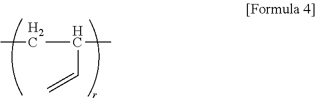
(wherein r represents an integer of 2 or higher. This formula includes polybutadiene containing 90% or more of 1, 2-repeating units and having a number average molecular weight in terms of styrene of 1000 to 200000.)

8. A multilayer wiring board comprising a plurality of copper wiring layers, and an insulating layer which is a cured product of a resin composition containing a compound having a carbon-carbon unsaturated double bond as a cross-linking component,
the copper wiring layers and the resin layers being adhered alternately,
the copper wiring having formed thereon a surface-treated layer comprising:
a metal layer (A) containing at least one metallic component selected from the group consisting of tin, zinc, nickel, chromium, cobalt and aluminium;
an oxide and/or hydroxide layer (B) of the metallic component on the metal layer (A);
an amino-silane coupling agent layer (C) having an amino group in its structure on the oxide and/or hydroxide layer (B); and
a vinyl-silane coupling agent layer (D) having a carbon-carbon unsaturated double bond on the amino-silane coupling agent layer (C).

9. The multilayer wiring board according to claim 8,
wherein the surface roughness of the copper wiring Ra is 0.1 to 0.3 μm.

10. The multilayer wiring board according to claim 8,
wherein the thickness of the metal layer (A) is 1 to 100 nm, the thickness of the oxide and/or hydroxide layer (B) is 1 to 100 nm, the thickness of the amino-silane coupling agent layer (C) is 1 to 150 nm, and the thickness of the vinyl-silane coupling agent layer having a carbon-carbon unsaturated double bond is 1 to 100 nm.

11. The multilayer wiring board according to claim 8,
wherein the vinyl-silane coupling agent having a carbon-carbon unsaturated double bond has any one functional group selected from the group consisting of a vinyl group, an acrylate group, a methacrylate group and a styrene group.

12. The multilayer wiring board according to claim 8,
wherein the dielectric tangent value of the insulating layer at 10 GHz is 0.001 to 0.006.

13. The multilayer wiring board according to claim 8,
wherein the insulating layer comprises a glass cloth.

14. The multilayer wiring board according to claim 8,
wherein the insulating layer comprises:
a modified polyphenylene ether resin having any one group selected from the group consisting of an allyl group, an acrylate group, a methacrylate group and styrene group in its structure; and
a cured product of at least one cross-linking component selected from the group consisting of compounds represented by formulae 1 to 4 below. 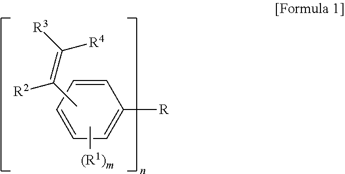
(wherein R represents a hydrocarbon skeleton; R¹ each represents the same or different C₁ to C₂₀ hydrocarbon group; R², R³ and R⁴ each represents the same or different hydrogen or a C₁ to C₆ hydrocarbon group; m represents an integer from 1 to 4; and n represents an integer of 2 or higher.) 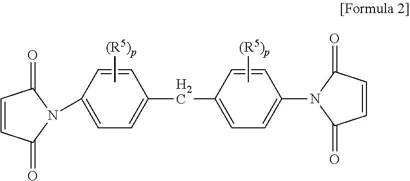
(wherein R⁵ each represents the same or different C₁ to C₄ hydrocarbon group; and p represents an integer from 1 to 4.) 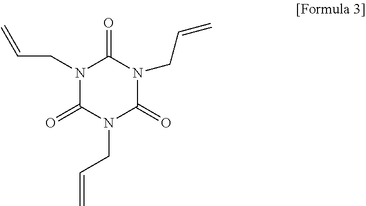
(this formula includes triallyl isocyanate or an oligomer which is a partial crosslinking product thereof.) 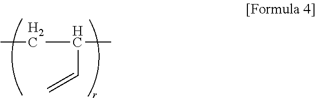
(wherein r represents an integer of 2 or higher. This formula includes polybutadiene having 90% or more of 1, 2-repeating units and a number average molecular weight in terms of styrene of 1000 to 200000.)

15. A laminate comprising a cured product of a prepreg which is a composite of a resin composition containing a compound having a carbon-carbon unsaturated double bond as a cross-linking component and a glass cloth, and a copper foil,
the surface roughness Ra of a first side of the copper foil being 0.1 to 0.3 μm,
the first side of the copper foil having a surface-treated layer formed thereon,
the surface-treated layer having a metal layer (A) containing at least one metallic component selected from the group consisting of tin, zinc, nickel, chromium, cobalt and aluminium,
an oxide and/or hydroxide layer (B) of the metallic component on the metal layer (A),
an amino-silane coupling agent layer (C) having an amino group in its structure on the oxide and/or hydroxide layer (B), and
a vinyl-silane coupling agent layer (D) having a carbon-carbon unsaturated double bond on the amino-silane coupling agent layer (C).

16. The laminate according to claim 15,
wherein the surface roughness of the surface of the copper wiring Ra is 0.1 to 0.3 μm.

17. The laminate according to claim 15,
wherein the thickness of the metal layer (A) is 1 to 100 nm, the thickness of the oxide and/or hydroxide layer (B) is 1 to 100 nm, the thickness of the amino-silane coupling agent layer (C) is 1 to 150 nm, and the thickness of the vinyl-silane coupling agent layer having a carbon-carbon unsaturated double bond is 1 to 100 nm.

18. The laminate according to claim 15,
wherein the vinyl-silane coupling agent having a carbon-carbon unsaturated double bond has any one functional group selected from the group consisting of a vinyl group, an acrylate group, a methacrylate group and a and styrene group.

19. The laminate according to claim 15,
wherein the dielectric tangent value of the insulating layer at 10 GHz is 0.001 to 0.006.

20. The laminate according to claim 15,
wherein the insulating layer comprises a glass cloth.

21. The laminate according to claim 15,
wherein the insulating layer contains a modified polyphenylene ether resin having any one group selected from the group consisting of an allyl group, an acrylate group, a methacrylate group and styrene group in its structure, and
a cured product of at least one cross-linking component selected from the group consisting of compounds represented by formulae 1 to 4 below. 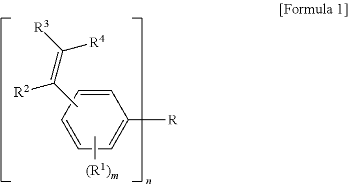
(wherein R represents a hydrocarbon skeleton; R¹ each represents the same or different C₁ to C₂₀ hydrocarbon group; R², R³ and R⁴ each represents the same or different hydrogen or a C₁ to C₆ hydrocarbon group; m represents an integer from 1 to 4; and n represents an integer of 2 or higher.) 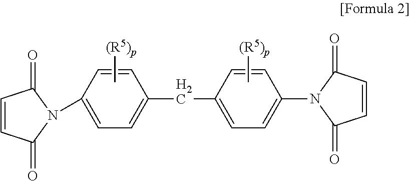
(wherein R⁵ each represents the same or different C₁ to C₄ hydrocarbon group; and p represents an integer from 1 to 4.) 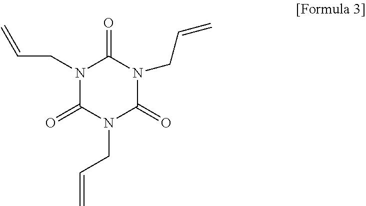
(This formula includes triallyl isocyanate or an oligomer which is a partial crosslinking product thereof.) 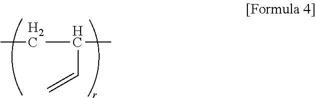
(wherein r represents an integer of 2 or higher. This formula includes polybutadiene containing 90% or more of 1,2-repeating units and a number average molecular weight in terms of styrene of 1000 to 200000.)

22. A copper foil which is adhered to an insulating layer comprising:
a cured resin product;
the copper foil having a surface roughness Ra of a first side thereof being 0.1 to 0.3 μm; and
a surface-treated layer being formed on the first side thereof,
the surface-treated layer having a metal layer (A) containing at least one metallic component selected from the group consisting of tin, zinc, nickel, chromium, cobalt and aluminium,
an oxide and/or hydroxide layer (B) of the metallic component on the metal layer (A),
an amino-silane coupling agent layer (C) having an amino group in its structure on the oxide and/or hydroxide layer (B), and
a vinyl-silane coupling agent layer (D) having a carbon-carbon unsaturated double bond on the amino-silane coupling agent layer (C).

23. The copper foil according to claim 16,
wherein the surface roughness Ra of the surface of the copper wiring is 0.1 to 0.3 μm.

24. The copper foil according to claim 22,
wherein the thickness of the metal layer (A) is 1 to 100 nm, the thickness of the oxide and/or hydroxide layer (B) is 1 to 100 nm, the thickness of the amino-silane coupling agent layer (C) is 1 to 150 nm, and the thickness of the vinyl-silane coupling agent layer having a carbon-carbon unsaturated double bond is 1 to 100 nm.

25. The copper foil according to claim 22,
wherein the vinyl-silane coupling agent having a carbon-carbon unsaturated double bond has any one functional group selected from the group consisting of a vinyl group, an acrylate group, a methacrylate group and a styrene group.
